(19) United States
(12) Patent Application Publication
(10) Pub. No.: US 2009/0139755 A1
(43) Pub. Date: Jun. 4, 2009

(54) SURFACE MOUNTED SEMICONDUCTOR DEVICE AND METHOD FOR MANUFACTURING SAME

(75) Inventors: Tomoyuki Kusano, Kagoshima (JP); Kazuhiro Ishibashi, Kagoshima (JP); Takaaki Onizuka, Kagoshima (JP)

Correspondence Address: HAMRE, SCHUMANN, MUELLER & LARSON P.C., P.O. BOX 2902-0902, MINNEAPOLIS, MN, 55402, US

(73) Assignee: MATSUSHITA ELECTRIC INDUSTRIAL CO., LTD., Osaka (JP)

(21) Appl. No.: 12/063,732

(22) PCT Filed: Aug. 17, 2006
(86) PCT No.: PCT/JP2006/316141

§ 371 Date: Feb. 13, 2008

(30) Foreign Application Priority Data
Aug. 17, 2005 (JP) 2005-236283

(51) Int. Cl. H05K 1/18; H05K 3/30

(52) U.S. Cl. 174/260; 29/832

(57) ABSTRACT

The present invention provides a surface mounted semiconductor device 1 formed by cutting an assembly board together with cathode wiring patterns 8 and anode wiring patterns 10 arranged on the assembly board on which light-emitting elements are mounted. When the surface mounted semiconductor device 1 is mounted on a mounting board with the cutting plane (bonding surface) facing the mounting board, the cathode wiring patterns 8 serve as cathode connection electrodes 15 and the anode wiring patterns 10 serve as anode connection electrodes 12. A substantially semi-elliptical notch 16 is formed in each of the anode connection electrodes 12. A substantially fan-shaped notch 14 is formed in the corner of each of the cathode connection electrodes 15. Thus, it is possible to provide a surface mounted semiconductor device that can prevent a poor connection and ensure the bond strength by forming a solder fillet reliably, even if burrs are produced on the connection electrodes formed by cutting the assembly board.

### TECHNICAL FIELD

The present invention relates to a surface mounted semiconductor device formed by cutting an assembly board on which a plurality of semiconductor elements are mounted into pieces. Furthermore, the present invention relates to a method for manufacturing such a surface mounted semiconductor device.

### BACKGROUND ART

A conventional surface mounted semiconductor device will be described with reference to FIG. 15 by taking an LED (light emitting diode) device as an example. An LED element 100 shown in FIG. 15 is a side-view type LED element, and light-emitting elements (not shown) mounted on a substrate 101 are sealed with a resin package 102.

When the LED element 100 is mounted on a mounting board by soldering, it is disposed so that connection electrodes 103 formed on the substrate 101 are perpendicular to the mounting board.

The LED element 100 is manufactured in the following manner: mounting the light-emitting elements on an assembly board on which wiring patterns for a plurality of the light-emitting elements are formed; sealing the light-emitting elements; and subsequently cutting the assembly board into pieces. Thus, the individual LED elements are provided.

The configuration of the assembly board used for manufacturing the conventional LED element 100 will be described with reference to FIGS. 16A and 16B. As shown in FIGS. 16A and 16B, wiring patterns 108, on each of which a light-emitting element 107 is mounted electrically, and wiring patterns 110 connected electrically to the respective light-emitting elements 107 via wires 109 are formed on a mounting surface 106 of an assembly board 105. These wiring patterns 108 and 110 are formed continuously from the mounting surface 106 to a back surface 111 opposite to the mounting surface 106. The wiring patterns 108 and 110 are formed so as to extend across a single piece of the substrate 101 when they are separated into each of the substrates 101.

In order to form the LED element 100 by cutting the assembly board 105 on which the light-emitting elements 107 are mounted into pieces, first, the light-emitting elements 107 are sealed with a resin to form the resin packages 102. Next, the back surface 111 of the assembly board 105 is attached to an adhesive sheet. Subsequently, the assembly board 105 is cut at the positions of cutting lines C from the mounting surface (106) side. Thus, the individual LED elements 100 can be obtained, as shown in FIG. 15. In other words, the wiring patterns 110 formed on both sides and the back surface 111 of the assembly board 105 are detached at the positions of the cutting lines C, resulting in the connection electrodes 103 that are independent in each of the LED elements 100.

Patent Document 1 describes a configuration in which the conventional surface mounted semiconductor device formed by cutting the assembly board into pieces, as described above, is connected to a mounting board with the connection electrode facing a connection wiring pattern provided on the mounting board.

### Patent Document 1: JP 10(1998)-150138 A

### DISCLOSURE OF INVENTION

### Problem to be Solved by the Invention

However, with the configuration disclosed in the Patent Document 1, burrs are produced on the cutting planes of the connection electrodes 103 formed by cutting the assembly board 105. FIG. 17 shows the burrs produced on the connection electrodes 103.

As shown in FIG. 17, when the assembly board 105 is cut to form the substrates 101, the cutting process is performed from the mounting surface (106) side, so that burrs 112 are produced on the connection electrodes 103 in the direction away from the substrate 101. If a solder paste is applied to a wiring pattern 114 of a mounting board 113, and then the LED element 100 is placed on the wiring pattern 114 and subjected to a reflow process while the burrs 112 are being produced, the burrs 112 become a barrier that tends to prevent the solder from forming a solder fillet. Furthermore, if the connection electrodes 103 are formed, e.g., by using Cu and Ni as a base material and plating the surface of the base material with Au, the Au plating comes off in the portions where the burrs 12 are produced, and the base material is exposed. The Au plating on the surface of the base material has excellent solder wettability, while Ni of the base material has low solder wettability. Therefore, the solder is repelled by Ni, making it more difficult to form a solder fillet.

For this reason, a poor connection may occur between the mounting board 113 and the LED element 100. Furthermore, the bond strength cannot be ensured, and thus the LED element 100 may peel off the mounting board 113.

It is an object of the present invention to provide a surface mounted semiconductor device that can prevent a poor connection and ensure the bond strength by forming a solder fillet reliably, even if burrs are produced on connection electrodes formed by cutting an assembly board.

### Means for Solving Problem

A surface mounted semiconductor device of the present invention includes a substrate, an electronic component mounted on the substrate, and a wiring electrode formed on a side of the substrate. The wiring electrode is formed so that at least one end of the wiring electrode reaches a boundary between the bottom of the substrate and the side contiguous to the bottom, and the wiring electrode is connected electrically to the electronic component. The bottom of the substrate is bonded to a wiring pattern of a mounting board on which the surface mounted semiconductor device is mounted. The wiring electrode has a notch in a portion of the at least one end that faces the boundary between the bottom of the substrate and the side contiguous to the bottom.

A method for manufacturing a surface mounted semiconductor device of the present invention includes the following: forming a wiring electrode on an assembly board; forming a substantially semi-circular notch or a substantially semi-elliptical notch in the wiring electrode; mounting an electronic component on the wiring electrode; and cutting the assembly board and the wiring electrode at a portion passing through the notch.

### EFFECTS OF THE INVENTION

In the present invention, the solder applied to the wiring pattern is raised along the edge of the notch, and a solder fillet can be formed reliably. Therefore, it is possible not only to prevent a poor connection, but also to ensure the bond strength.

### BRIEF DESCRIPTION OF DRAWINGS

FIG. 1 is a perspective view of an LED as an example of a surface mounted semiconductor device according to a first embodiment of the present invention.

FIG. 2A is a view for explaining a substrate on which light-emitting elements are mounted, observed from the mounting surface side.

FIG. 2B is a view of the substrate observed from the back surface side opposite to the mounting surface.

FIG. 3 is a plan view showing an assembly board of the surface mounted semiconductor device according to the first embodiment of the present invention.

FIG. 4 is a view for explaining the assembly board of the surface mounted semiconductor device according to the first embodiment of the present invention, observed from the mounting surface side.

FIG. 5 is a view for explaining the assembly board of the surface mounted semiconductor device according to the first embodiment of the present invention, observed from the back surface side opposite to the mounting surface.

FIG. 6 is a diagram for explaining a state in which the LED as an example of the surface mounted semiconductor device according to the first embodiment of the present invention is mounted on and soldered to a mounting board.

FIG. 7 is a perspective view of an LED as an example of a surface mounted semiconductor device according to a second embodiment of the present invention.

FIG. 8A is a view for explaining a substrate on which light-emitting elements are mounted, observed from the mounting surface side.

FIG. 8B is a view of the substrate observed from the back surface side opposite to the mounting surface.

FIG. 8C is a side view of the substrate.

FIG. 9 is a plan view showing an assembly board of the surface mounted semiconductor device according to the second embodiment of the present invention.

FIG. 10 is a view for explaining the assembly board of the surface mounted semiconductor device according to the second embodiment of the present invention, observed from the mounting surface side.

FIG. 11 is a view for explaining the assembly board of the surface mounted semiconductor device according to the second embodiment of the present invention, observed from the back surface side opposite to the mounting surface.

FIG. 12 is a view for explaining the assembly board of the surface mounted semiconductor device according to the second embodiment of the present invention, observed from the side of the mounting surface.

FIG. 13 is a diagram for explaining a state in which the LED as an example of the surface mounted semiconductor device according to the second embodiment of the present invention is mounted on and soldered to a mounting board.

FIG. 14 is a diagram for explaining a state in which the LED as an example of the surface mounted semiconductor device according to the second embodiment of the present invention is mounted on and soldered to a mounting board.

FIG. 15 is a perspective view of an LED as an example of a conventional surface mounted semiconductor device.

FIG. 16A is a view for explaining an assembly board of a conventional surface mounted semiconductor device, observed from the mounting surface side.

FIG. 16B is a view of the assembly board observed from the back surface side opposite to the mounting surface.

FIG. 17 is a diagram for explaining a state in which a conventional surface mounted semiconductor device is mounted on and soldered to a mounting board.

### DESCRIPTION OF REFERENCE NUMERALS

1, 31 LED element

2, 32 substrate

3, 33 resin package

4, 52 bonding surface (second bonding surface)

5, 34 wiring pattern

6, 35 mounting surface (first bonding surface)

7, 36 light-emitting element (electronic component)

8, 37 cathode wiring pattern

10, 39 anode wiring pattern

11 back surface

12, 42 anode connection electrode

13 side

14 substantially fan-shaped notch

15, 41 cathode connection electrode

16 substantially semi-elliptical notch

17, 43 mounting-surface-side resist

18, 44 polarity indication resist

19, 50 assembly board

19a, 50a long hole

20 substantially semi-circular notch

21 substantially elliptical notch

22, 51 silver paste

23 mounting board

26 connection wiring pattern

40 back surface

41a, 42a first connecting surface

41b, 42b second connecting surface

41c, 42c notch

### BEST MODE FOR CARRYING OUT THE INVENTION

In the surface mounted semiconductor device of the present invention, the notch may be formed so that an angle between the edge of the notch and the edge of a connection electrode on the bonding surface side is an obtuse angle. With this configuration, the distance between the notch of the connection electrode and the solder applied to the mounting board becomes shorter compared to the case where the angle is a right angle. This allows the solder applied to the mounting board to reach easily the notch of the connection electrode when the surface mounted semiconductor device is mounted on the mounting board. Thus, the solder can flow around the burrs and spread on the connection electrode easily.

The notch may be formed so as to be open toward the bonding surface side of the connection electrode. With this configuration, the solder applied to the mounting board is raised from both sides of the opening of the notch and travels along the notch of the connection electrode, where no burrs occur. Therefore, the solder is more likely to flow around the burrs and adhere to the connection electrode.

The notch may be substantially in the form of a semi-ellipse. With this configuration, even if the cutting position is shifted to the inside of the substrate, it is possible to suppress the occurrence of burrs in a large area. For example, assuming that the notch has a triangular shape that is open toward the bonding surface side of the connection electrode, if the cutting position is shifted to the inside of the substrate while the wiring patterns of the assembly board are cut to form the connection electrodes, the edge of the connection electrode on the bonding surface side becomes longer in proportion to the shift of the cutting position, which in turn increases the length of burrs that are produced along the edge of the connection electrode. When the notch is substantially semi-elliptical in shape, even if the cutting position is shifted to the inside of the substrate, the degree of increasing the length of the edge of the connection electrode is lower compared to the triangular notch. Therefore, it is possible to suppress the occurrence of burrs in a large area.

The notch may be formed so as to divide equally the edge of the connection electrode on the bonding surface side. With this configuration, the solder that has been raised along the notch of the connection electrode adheres to the connection electrode uniformly, and then joins together on the connecting electrode. Thus, the solder is less likely to be uneven, and can join to form a solder fillet that covers the whole connection electrode.

The notch may be formed in any corner of the connection electrode on the bonding surface side. With this configuration, the solder can flow around the burrs produced on the cutting portions. That is, when the connection electrode is not broad, or is located at the end portion of the surface mounted semiconductor device, it may be difficult to form the notch so as to be open toward the bonding surface side of the connection electrode. In such a case, the notch can be formed in any corner of the connection electrode on the bonding surface side, and thus allows the solder to flow around the burrs produced on the cutting portions.

The notch may be substantially in the form of a fan. With this configuration, even if the cutting position is shifted to the inside of the substrate, the degree of increasing the length of the edge of the connection electrode is lower compared to a linear notch. Therefore, it is possible to suppress the occurrence of burrs in a large area. For example, assuming that a notch consisting of straight lines is formed in a corner of the connection electrode on the bonding surface side, if the cutting position is shifted to the inside of the substrate while the wiring patterns of the assembly board are cut to form the connection electrodes, the edge of the connection electrode on the bonding surface side becomes longer in proportion to the shift of the cutting position, which in turn increases the length of burrs that are produced along the edge of the connection electrode. When the notch is substantially in the form of a fan, even if the cutting position is shifted to the inside of the substrate, the degree of increasing the length of the edge of the connection electrode is lower compared to the linear notch. Therefore, it is possible to suppress the occurrence of burrs in a large area.

The notch may be formed so as to extend across adjacent connection electrodes that meet at a corner of the substrate. With this configuration, even if the burrs protrude so as to block the lower end portion of the notch formed in one of the connection electrodes, the solder can spread from the notch formed in the other, so that a more reliable connection with the mounting board can be achieved. The burrs produced during the cutting of the assembly board can protrude in the direction of rotation of the blade used. In other words, the burrs produced on the bonding surface side of each of the adjacent connection electrodes present at the corner of the substrate are oriented in the same direction. By forming the notch so as to extend across the adjacent connection electrodes at the corner of the substrate, when the burrs of one connection electrode protrude so as to block the lower end portion of the notch, the burrs of the other connection electrode can protrude in the direction away from the notch. Therefore, even if the burrs protrude so as to block the lower end portion of the notch formed in one of the connection electrodes, the solder can spread from the notch formed in the other, so that a more reliable connection with the mounting board can be achieved.

### First Embodiment

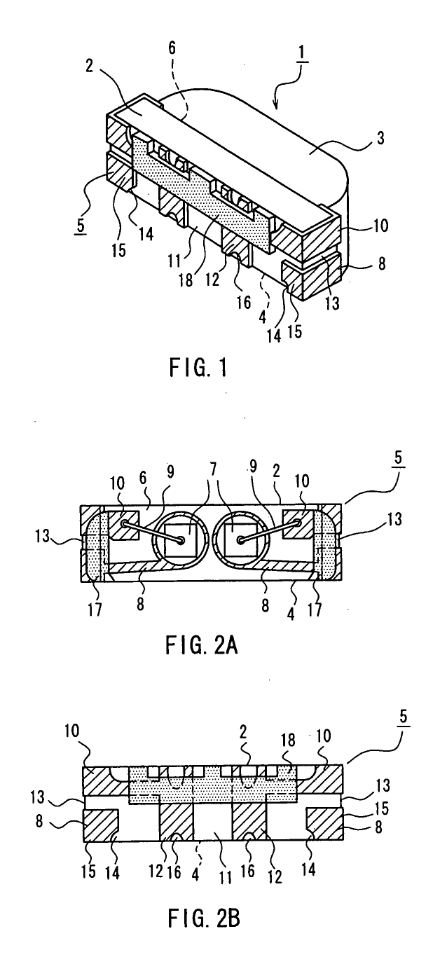

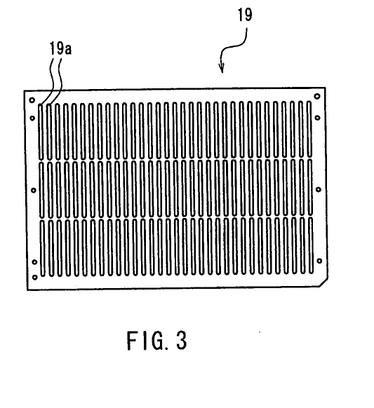

FIG.1 is a perspective view of an LED element as an example of a surface mounted semiconductor device according to a first embodiment of the present invention. FIG. 2A is a plan view of a substrate observed from the mounting surface side. FIG. 2B is a plan view of the substrate observed from the back surface side opposite to the mounting surface.

As shown in FIG. 1, an LED element 1 as an example of the surface mounted semiconductor device includes a substrate 2, light-emitting elements (not shown) mounted on the substrate 2, and a resin package 3 for sealing the light-emitting elements. The LED element 1 is formed as a side-view type LED element that is mounted on a mounting board and emits light substantially parallel to the surface of the mounting board.

As shown in FIGS. 2A and 2B, the substrate 2 has a length of about 2.5 mm in a longitudinal direction. Wiring patterns 5 are formed axisymmetrically on both surfaces (a mounting surface 6 and a back surface 11) of the substrate 2, and two light-emitting elements 7 are mounted on the mounting surface 6. The wiring patterns 5 are made of a base material including Cu and Ni, and the base material is plated with Au.

The wiring pattern 5 on the mounting surface 6 includes cathode wiring patterns 8, on each of which the light-emitting element 7 is mounted, and anode wiring patterns 10 connected to the respective light-emitting elements 7 via wires 9. As shown in FIG. 1, the cathode wiring patterns 8 and the anode wiring patterns 10 are disposed parallel to each other on both sides of the substrate 2, and formed in a substantially U shape so as to extend from the mounting surface 6 to the back surface 11.

In order to use the cathode wiring patterns 8 as cathode connection electrodes 15 when the LED element 1 is mounted on a mounting board, each of the cathode wiring patterns 8 is formed contiguously on the side 13 and the back surface 11 of the substrate 2 up to a bonding surface 4. Moreover, a substantially fan-shaped notch 14 is formed in a corner of the end portion of each of the cathode connection electrodes 15 on the bonding surface (4) side.

In order to use the anode wiring patterns 10 as anode connection electrodes 12 when the LED element 1 is mounted on a mounting board, as shown in FIG. 2B, each of the anode wiring patterns 10 is arranged on the back surface 11 of the substrate 2 so as to extend in a vertical direction. Moreover, a substantially semi-elliptical notch 16 is formed in the end portion of each of the anode wiring patterns 10 on the bonding surface (4) side. The anode connection electrodes 12 have a width of about 0.34 mm.

Mounting-surface-side resists 17 are placed on both sides 13 of the mounting surface 6 of the substrate 2. The mounting-surface-side resists 17 serve as a cushion when they come into contact with a die surrounding a cavity for forming the resin package 3. Each of the mounting-surface-side resists 17 is formed so as to traverse the cathode wiring pattern 8 and the anode wiring pattern 10.

A polarity indication resist 18 is placed on the back surface 11 of the substrate 2. The polarity indication resist 18 serves as a cushion when it comes into contact with a die surrounding a cavity for forming the resin package 3. The polarity indication resist 18 is used to indicate the positions of the anode wiring patterns 10 on the back surface 11 of the substrate 2.

Hereinafter, a method for manufacturing the surface mounted semiconductor device according to the first embodiment will be described.

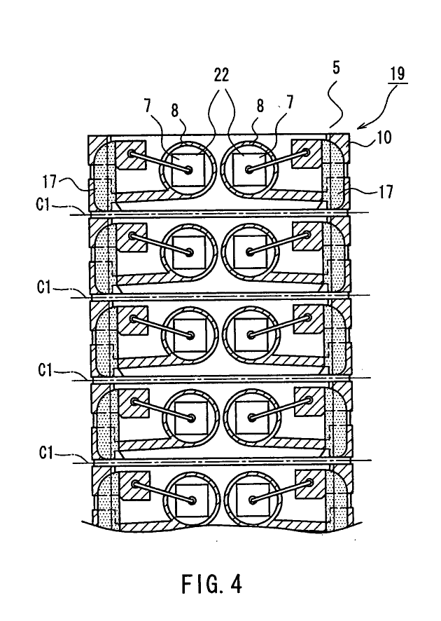

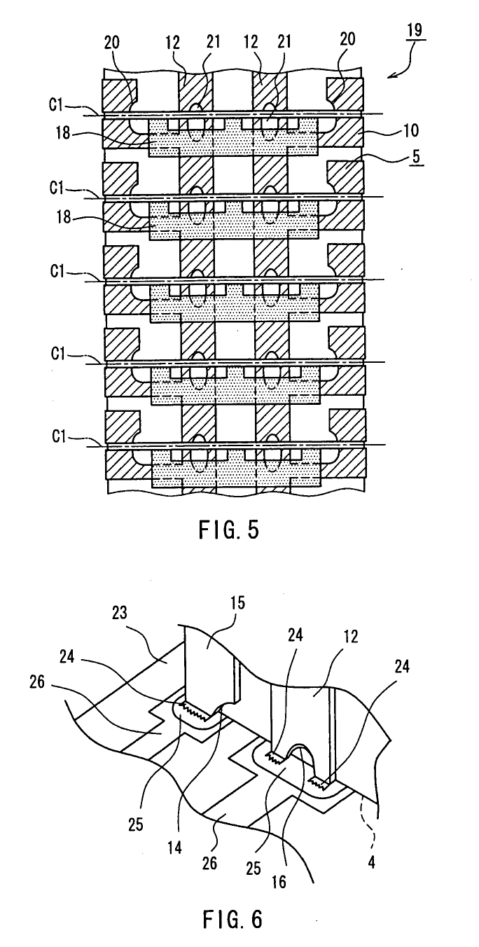

FIG. 3 is a plan view showing an assembly board of the surface mounted semiconductor device according to the first embodiment. FIG. 4 is a plan view for explaining the assembly board of the surface mounted semiconductor device according to the first embodiment, observed from the mounting surface side. FIG. 5 is a plan view for explaining the assembly board of the surface mounted semiconductor device according to the first embodiment, observed from the back surface side.

As shown in FIG.3, first, an assembly board 19 having a substantially rectangular shape is prepared, which is a basis of the individual substrates 2. In the assembly board 19, a plurality of pairs of long holes 19a are arranged in rows and columns. The wiring patterns 5 in each of the substrates 2 are formed continuously in series in a region sandwiched between each pair of long holes 19a.

As shown in FIG. 5, in the wiring patterns 5 of the assembly board 19, the cathode wiring patterns 8 and the adjacent anode wiring patterns 10 are connected so as to extend across the two adjacent substrates 2, and a substantially semi-circular notch 20 is formed in each of the connected portions. Furthermore, substantially elliptical notches 21 are formed in the anode wiring patterns 10, which are to be the anode connection electrodes 12, so as to extend across the two adjacent substrates 2.

Each of the substantially elliptical notches 21 is formed at a position that equally divides the edge of the anode wiring pattern 10 on the bonding surface (4) side. This is because when the substantially elliptical notches 21 are cut into the substantially semi-elliptical notches 16 as shown in FIGS. 1, 2A, and 2B, solder is raised along the arcs on both sides of the substantially semi-elliptical notch 16 and adheres uniformly to the anode connection electrode 12, so that an uneven connection is less likely to occur. Accordingly, the solder spreading on both sides of the substantially semi-elliptical notch 16 joins together on the anode connection electrode 12, thereby forming a solder fillet that covers the whole of the end portion of the anode connection electrode 12.

As shown in FIG. 5, cutting lines C1 indicating the positions at which the assembly board 19 is cut do not pass through the centers of the notches 20 and 21, but are shifted upward in the figure. When the assembly board 19 is cut along such cutting lines C1, the notches 20 and 21 on the bonding surface (4) side become smaller in area than those on the other side.

Next, the mounting-surface-side resists 17 and the polarity indication resists 18 are formed on the assembly board 19 on which the wiring patterns 5 have been formed. Then, a silver paste 22 is applied to the predetermined positions of the cathode wiring patterns 8, and two light-emitting elements 7 are mounted on each of the wiring patterns 8. Subsequently, a resin is molded to form each of the resin packages 3 (see FIG. 1). Thereafter, the resin packages 3 are oriented upward, and the back surface 11 is attached to an adhesive sheet. Finally, the assembly board 19, together with the wiring patterns 5, is cut along the cutting lines C1.

In this manner, the individual LED elements 1 are completed. By cutting the assembly board 19 at the cutting lines C1, as shown in FIG. 2, the substantially semi-circular notches 20 become the substantially fan-shaped notches 14 formed in the corners on the bonding surface (4) side, and the cathode connection electrodes 15 are formed. Furthermore, the substantially elliptical notches 21 become the substantially semi-elliptical notches 16 formed so as to be open toward the bonding surface (4) side, and the anode connection electrodes 12 are formed. The cutting planes of the assembly board 19 that has been cut at the cutting lines C1 serve as the bonding surfaces 4 of the individual substrates 2.

Next, a state in which the surface mounted semiconductor device according to the first embodiment is mounted on and soldered to a mounting board will be described.

FIG. 6 is a perspective view showing a state in which an LED element as an example of the surface mounted semiconductor device according to the first embodiment is mounted on and soldered to a mounting board. In FIG. 6, the end portions of the anode connection electrode 12 and the cathode connection electrode 15 are magnified.

As shown in FIG. 6, when the assembly board 19 is cut into pieces at the cutting lines C1, burrs 24 are produced on the edges of the anode connection electrode 12 and the cathode connection electrode 15 on the bonding surface (4) side. The burrs 24 are produced because the Au plating on the anode connection electrode 12 and the cathode connection electrode 15 comes off and Ni of the base material is exposed. However, since the notches 14 and 16 have been formed in the cathode connection electrode 15 and the anode connection electrode 12 before cutting the assembly board 19 at the cutting lines C1, no burrs occur in the portion of the cathode connection electrode 15 around the notch 14 and the portion of the anode connection electrode 12 around the notch 16.

Next, the LED element 1 is aligned and mounted on a connection wiring pattern 26 of a mounting board 23 on which solder 25 has been applied.

Next, a reflow process is performed with the LED element 1 mounted on the mounting board 23. Then, the solder 25 applied to the mounting board 23 is raised due to the interfacial tension along the notch 16 of the anode connection electrode 12 and the notch 14 of the cathode connection electrode 15, where the burrs 24 are not produced. Therefore, the solder 25 flows around the burrs 24 on the cutting portions rather than through them, and spreads and adheres to the surface of each of the anode connection electrode 12 and the cathode connection electrode 15. That is, the solder 25 travels in the form of a film with a thickness larger than the burrs 24 on the surface of each of the anode connection electrode 12 and the cathode connection electrode 15. Moreover, the solder 25 flows over the burrs 24 and joins to the solder 25 on the mounting board 23, and consequently the solder 25 further increases in its extent and thickness. Thus, the solder 25 spreads from the upper to lower portions like skirts of a mountain, so that an excellent solder fillet can be formed.

Accordingly, the LED element 1 and the mounting board 23 reliably can be connected electrically, and the bond strength can be ensured. Furthermore, even if the Au plating comes off and Ni with low wettability is exposed, the solder 25 spreads while flowing around the burrs 24, and thus a solder fillet can be formed reliably.

The notches 16 and 14 are formed so that each of the angles between the edge of the notch 16 and the edge of the anode connection electrode 12 on the bonding surface (4) side and between the edge of the notch 14 and the edge of the cathode connection electrode 15 on the bonding surface (4) side is an obtuse angle, although those angles are only slightly larger than 90°. The distances between the solder 25 applied to the mounting board 23 and each of the notch 16 of the anode connection electrode 12 and the notch 14 of the cathode connection electrode 15 become shorter in the case of an obtuse angle than in the case of a right angle. This allows the solder 25 applied to the mounting board 23 to reach easily the notch 16 of the anode connection electrode 12 and the notch 14 of the cathode connection electrode 15 when the LED element 1 is mounted on the mounting board 23. Thus, the solder 25 can flow around the burrs 24 and spread more easily.

When the assembly board 19 is cut after forming the resin packages 3, an adhesive sheet may be attached to the side of the resin packages 3, thereby directing the burrs 24 to be produced on the anode connection electrode 12 and the cathode connection electrode 15 toward the inside of the substrate 2. This makes it possible to avoid the situation where the burrs 24 become a barrier, and a solder fillet cannot be formed on the anode connection electrode 12 and the cathode connection electrode 15. However, if the assembly board 19 is cut with the adhesive sheet on the side of the resin packages 3, the cutting lines C1 may deviate, since the assembly board 19 is not stable due to the vibrations of a blade or the like during cutting. Therefore, the assembly board 19 should be cut with the resin packages 3 facing up and the adhesive sheet being attached to the back surface 11.

As described above, in this embodiment, the notches 14 and 16 are formed in the end portions of the anode connection electrode 12 and the cathode connection electrode 15 on the bonding surface side. Therefore, when the assembly board 5 is cut, the notches 14 and 16 are not present at the cutting positions, and no burrs occur. Accordingly, the solder can start to adhere to the notches 14 and 16 of the connection electrodes, so that a solder fillet can be formed reliably and a poor connection can be prevented. Furthermore, the bond strength can be ensured.

### Second Embodiment

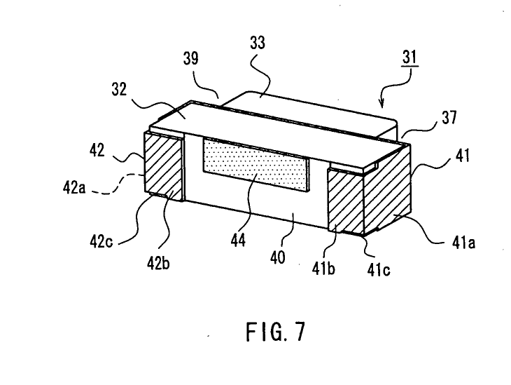

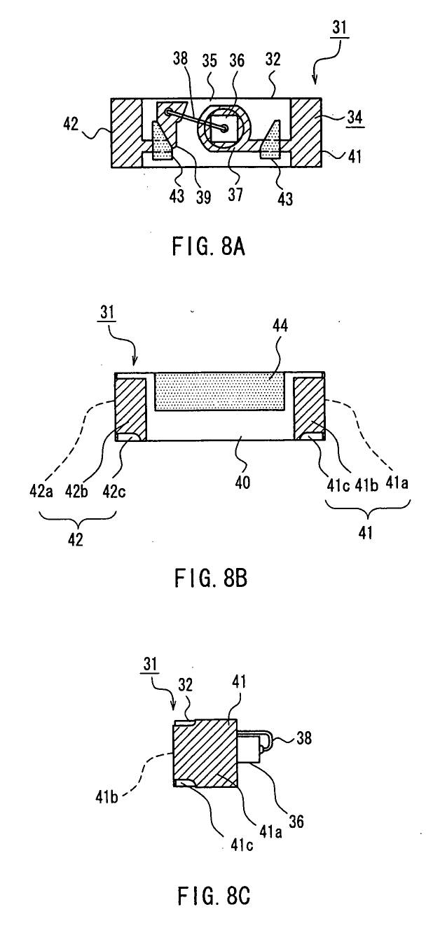

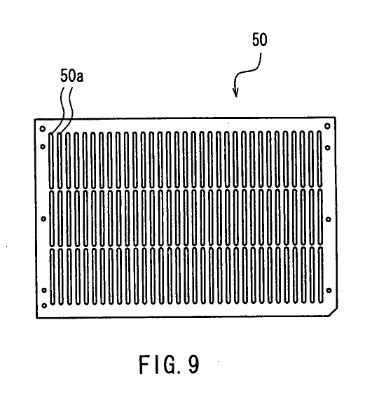

FIG. 7 is a perspective view of an LED element as an example of a surface mounted semiconductor device according to a second embodiment. FIG. 8 is a plan view showing the configuration of a substrate. FIG. 8A is a view of the substrate on which a light-emitting element is mounted, observed from the mounting surface side. FIG. 8B is a view of the substrate observed from the back surface side. FIG. 8C is a side view of the substrate.

As shown in FIG. 7, an LED element 31 as an example of the surface mounted semiconductor device includes a substrate 32, a light-emitting element (not shown) mounted on the substrate 32, and a resin package 33 for sealing the light-emitting element. The LED element 31 is formed as a side-view type LED element that is mounted on a mounting board and emits light parallel to the surface of the mounting board.

As shown in FIGS. 8A to 8C, the substrate 32 has a length of about 1.8 mm in a longitudinal direction. Wiring patterns 34 are formed on both surfaces of the substrate 32, and a single light-emitting element 36 is mounted on a mounting surface 35. The wiring patterns 34 are made of a base material including Cu and Ni, and the base material is plated with Au.

The wiring pattern 34 on the mounting surface 35 includes a cathode wiring pattern 37, on which the light-emitting element 36 is mounted, and an anode wiring pattern 39 connected to the light emitting element 36 via a wire 38. As shown in FIG. 7, the cathode wiring pattern 37 and the anode wiring pattern 39 are formed on both sides of the substrate 32 in a U shape so as to extend from the mounting surface 35 to a back surface 40 opposite to the mounting surface 35. In the cathode wiring pattern 37 and the anode wiring pattern 39 formed on both sides of the substrate 32, the portions to be connected to a mounting pattern of a mounting board when the LED element 31 is mounted on the mounting board serve as a cathode connection electrode 41 and an anode connection electrode 42, respectively.

A notch 41c and a notch 42c are formed in the cathode connection electrode 41 and the anode connection electrode 42 so as to extend across the adjacent first and second connecting surfaces 41a, 41b and the adjacent first and second connecting surfaces 42a, 42b present at the corners of the substrate 32, respectively.

Mounting-surface-side resists 43 are placed on the mounting surface 35 of the substrate 32. The mounting-surface-side resists 43 serve as a cushion on both sides of the substrate 32 when they come into contact with a die surrounding a cavity for forming the resin package 33. Each of the mounting-surface-side resists 43 is formed so as to cross the cathode wiring pattern 37 and the anode wiring pattern 39.

A polarity indication resist 44 is placed on the back surface 40 of the substrate 32. The polarity indication resist 44 serves as a cushion when the substrate 32 comes into contact with a die during the formation of the resin package 33. The polarity indication resist 44 also can indicate the polarities of the cathode wiring pattern 37 and the anode wiring pattern 39.

Hereinafter, a method for manufacturing the surface mounted semiconductor device according to the second embodiment will be described.

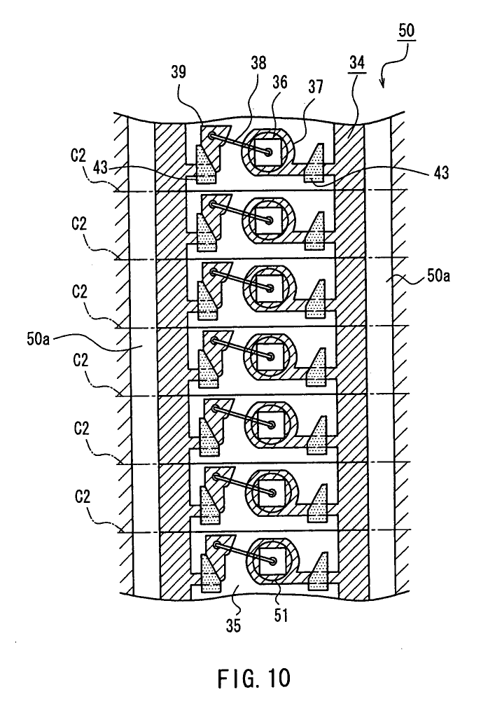

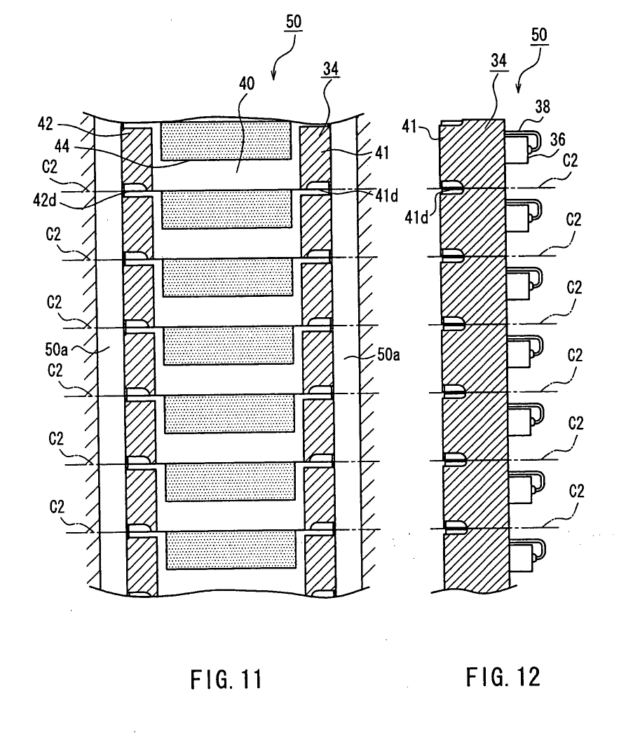

FIG. 9 is a plan view showing an assembly board of the surface mounted semiconductor device according to the second embodiment. FIG. 10 is a plan view for explaining the assembly board of the surface mounted semiconductor device according to the second embodiment, observed from the mounting surface side. FIG. 11 is a plan view for explaining the assembly board of the surface mounted semiconductor device according to the second embodiment, observed from the back surface side opposite to the mounting surface. FIG. 12 is a plan view for explaining the assembly board of the surface mounted semiconductor device according to the second embodiment, observed from the side of the mounting surface.

As shown in FIGS. 9 to 12, first, an assembly board 50 having a substantially rectangular shape is prepared, which is a basis of the individual substrates 32. In the assembly board 50, a plurality of pairs of long holes 50a are arranged in rows and columns.

Then, the wiring patterns 34 for both surfaces of each of the substrates 32 are formed continuously in series in a region sandwiched between each pair of long holes 50a of the assembly board 50.

In the wiring patterns 34 of the assembly board 50, the cathode wiring patterns 37 are formed continuously on one side and the anode wiring patterns 39 are formed continuously on the other side. By forming each of the cathode wiring patterns 37 so as to reach the back surface 40, the cathode connection electrode 41 can be formed in a substantially U shape. Similarly, by forming each of the anode wiring patterns 39 so as to reach the back surface 40, the anode connection electrode 42 can be formed in a substantially U shape.

In the cathode connection electrode 41, the notch 41c is formed so as to extend across the first connecting surface 41a (located on the side) and the second connecting surface 41b (located on the back surface 40) and to be open toward the back surface (40) side. In the anode connection electrode 42, the notch 42c is formed so as to extend across the first connecting surface 42a (located on the side) and the second connecting surface 42b (located on the back surface 40) and to be open toward the back surface (40) side.

Next, the mounting-surface-side resists 43 and the polarity indication resists 44 are formed on the assembly board 50 on which the wiring patterns 34 have been formed. Then, a silver paste 51 is applied to the predetermined positions of the cathode wiring patterns 37, and the light-emitting element 36 is mounted on each of the wiring patterns 37.

Subsequently, a resin is molded to form each of the resin packages 33 (see FIG. 7).

Thereafter, the resin packages 33 are directed upward, and the back surface 40 is attached to an adhesive sheet.

Finally, the assembly board 50, together with the wiring patterns 34, is cut along cutting lines C2 using a blade or the like, thus providing the individual LED elements 31.

Next, a state in which the surface mounted semiconductor device according to the second embodiment is mounted on and soldered to a mounting board will be described.

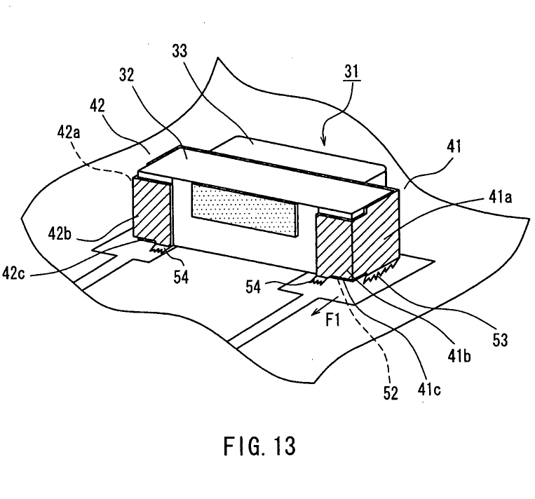

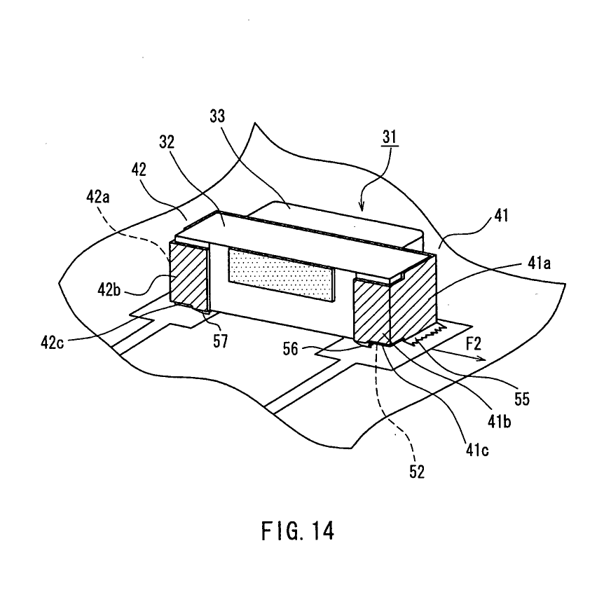

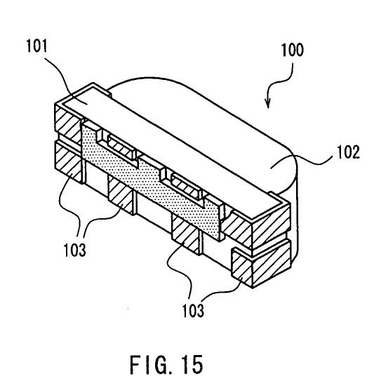

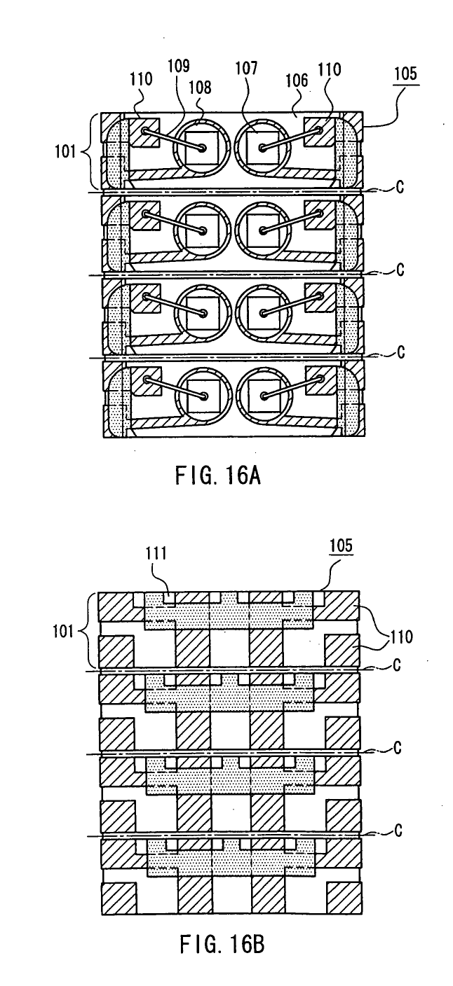

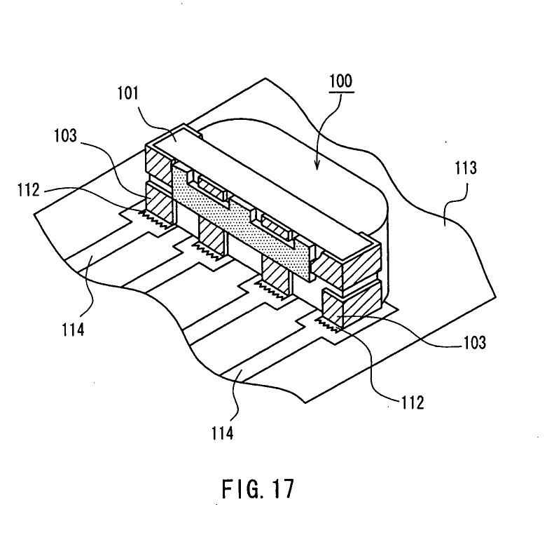

FIGS. 13 and 14 are diagrams for explaining a state in which an LED element as an example of the surface mounted semiconductor device according to the second embodiment is mounted on and soldered to a mounting board

As shown in FIG. 13, when the assembly board 50 is cut into pieces at the cutting lines C2 with a blade that is rotated in a rotation direction F1, burrs 53, 54 may be produced on the edges of the cathode connection electrode 41 and the anode connection electrode 42 on a bonding surface (52) side along the rotation direction F1. The burrs 53, 54 are produced because the Au plating on the anode connection electrode 42 and the cathode connection electrode 41 comes off and Ni of the base material is exposed, so that the solder wettability is low. The burrs 53 produced on the lower ends of the first connecting surfaces 41a, 42a (burrs on the anode connection electrode 42 are not shown in FIG. 13) protrude toward the notches 41c, 42c and may interfere with the adhesion of the solder to the notches 41c, 42c. However, the burrs 54 produced on the lower ends of the second connecting surfaces 41b, 42b protrude in the direction away from the notches 41c, 42c. That is, even if the burrs 53 protrude so as to block the lower end portions of the notches 41c, 42c formed in the first connecting surfaces 41a, 42a, the solder can spread from the notches 41c, 42c formed in the second connecting surfaces 41b, 42b to the respective surfaces of the cathode connection electrode 41 and the anode connection electrode 42. Thus, the LED element can be connected more reliably to the mounting board.

Moreover, when the assembly board 50 is cut into pieces at the cutting lines C2 with a blade that is rotated in a rotation direction F2, as shown in FIG. 14, burrs 55 to 57 may be produced on the edges of the cathode connection electrode 41 and the anode connection electrode 42 on the bonding surface (52) side along the rotation direction F2. In this case, since the burrs 56 produced on the second connecting surface 41b of the cathode connection electrode 41 protrude so as to block the lower end portion of the notch 41c, the solder is not likely to adhere to the second connecting surface 41b. However, the burrs 55 produced on the first connecting surface 41a of the cathode connection electrode 41 protrude in the direction away from the notch 41c. Therefore, the solder can spread from the first connecting surface 41a of the cathode connection electrode 41. At this time, the burrs 57 produced on the second connecting surface 42b of the anode connection electrode 42 protrude in the direction away from the notch 42c, and therefore will not be a problem. Moreover, burrs (not shown) produced on the first connecting surface 42a of the anode connection electrode 42 protrude so as to extend from the first connecting surface 42a to the substrate 32, and therefore will not be a problem. Accordingly, the solder can spread on the anode connection electrode 42 in a state where almost no burrs occur.

As described above, the notches 41c, 42c are formed so as to extend across the adjacent first and second connecting surfaces 41a, 41b and the adjacent first and second connecting surfaces 42a, 42b present at the corners of the substrate 32, respectively, which has been obtained by cutting the assembly board 50 into pieces. Therefore, even if the cutting of the assembly board 50 is performed in either direction of the arrow F1 (FIG. 13) or F2 (FIG. 14), the solder can adhere reliably to the cathode connection electrode 41 and the anode connection electrode 42.

The present invention is not limited to the above-described embodiments. For example, in the first embodiment, the notch is substantially semi-elliptical, but may be trapezoidal in shape. Moreover, the substantially semi-elliptical 16 is formed in one portion of the anode connection electrode 12, but may be formed in a plurality of portions depending on the width of the anode connection electrode 12.

### INDUSTRIAL APPLICABILITY

The present invention is suitable for a surface mounted semiconductor device that is formed by cutting an assembly board into pieces, since the present invention can prevent a poor connection and ensure the bond strength by forming a solder fillet reliably, even if burrs are produced on the connection electrodes formed by cutting the assembly board.

1. A surface mounted semiconductor device comprising:
a substrate;
an electronic component mounted on the substrate; and
a wiring electrode formed on a side of the substrate,
wherein the wiring electrode is formed so that at least one end of the wiring electrode reaches a boundary between a bottom of the substrate and the side contiguous to the bottom, and the wiring electrode is connected electrically to the electronic component,
wherein the bottom of the substrate is bonded to a wiring pattern of a mounting board on which the surface mounted semiconductor device is mounted, and
wherein the wiring electrode has a notch in a portion of the at least one end that faces the boundary between the bottom of the substrate and the side contiguous to the bottom.

2. The surface mounted semiconductor device according to claim 1, wherein the notch is formed so that an angle between an edge of the notch and an edge of the wiring electrode on the bonding surface side is an obtuse angle.

3. The surface mounted semiconductor device according to claim 1, wherein the notch is formed so as to be open toward the bonding surface side of the wiring electrode.

4. The surface mounted semiconductor device according to claim 3, wherein the notch is substantially in the form of a semi-ellipse.

5. The surface mounted semiconductor device according to claim 1, wherein the notch is formed so as to divide equally the edge of the wiring electrode on the bonding surface side.

6. The surface mounted semiconductor device according to claim 1, wherein the notch is formed in any corner of the wiring electrode on the bonding surface side.

7. The surface mounted semiconductor device according to claim 6, wherein the notch is substantially in the form of a fan.

8. The surface mounted semiconductor device according to claim 1, wherein the notch is formed so as to extend across adjacent wiring electrodes that meet at a corner of the substrate.

9. A method for manufacturing a surface mounted semiconductor device comprising:
forming a wiring electrode on an assembly board;
forming a substantially semi-circular notch or a substantially semi-elliptical notch in the wiring electrode;
mounting an electronic component on the wiring electrode; and
cutting the assembly board and the wiring electrode at a portion passing through the notch.
